(19) United States
(12) Patent Application Publication
(10) Pub. No.: US 2002/0175413 A1
(43) Pub. Date: Nov. 28, 2002

(54) Method for utilizing tungsten barrier in contacts to silicide and structure produced therby

(75) Inventors: Louis D. Lanzerotti, Burlington, VT (US); Randy William Mann, Jericho, VT (US); Glen Lester Miles, Essex Junction, VT (US); William Joseph Murphy, Essex Junction, VT (US); Daniel Scott Vanslette, Highgate Springs, VT (US)

Correspondence Address: MCGINN & GIBB, PLLC, 8321 OLD COURTHOUSE ROAD, SUITE 200, VIENNA, VA, 22182-3817, US

(73) Assignee: International Business Machines Corporation, Armonk, NY (US)

(21) Appl. No.: 09/820,591

(22) Filed: Mar. 29, 2001

(51) Int. Cl. H01L 21/4763; H01L 21/44; H01L 23/48; H01L 23/52; H01L 29/40

(52) U.S. Cl. 257/751; 438/653; 438/654; 257/753; 257/754; 257/763

(57) ABSTRACT

A method of forming a liner (and resultant structure) in a contact includes depositing a first layer of refractory metal, annealing the first layer, and sputter depositing a second layer of refractory metal or a compound or an alloy thereof, over the first layer.

### BACKGROUND OF THE INVENTION

1. Field of the Invention

The present invention generally relates to a method for forming a semiconductor device and structure formed by the method, and more particularly to a method for forming a liner in a contact of a semiconductor device.

2. Description of the Related Art

Conventional methods of forming a semiconductor device have not successfully integrated sputtered tungsten at contacts to silicide regardless of whether the tungsten has been deposited by conventional plasma vapor deposition (PVD) or ionized plasma vapor deposition (IPVD). Indeed, typically, chemical vapor deposited Titanium nitride (TiN) is employed. However, while TiN is a good adherent, there are a number of problems, and thus an anneal is required.

It is noted that, for purposes of the present invention, PVD is standard sputtering in which the metal atoms are neutral (no charge) and a manner of how such atoms arrive at the wafer is purely determined by line-of-sight trajectory paths. In contrast, IPVD uses metal atoms being sputtered which are ionized prior to reaching the wafer, and thus their trajectories can be affected/influenced by an electrical field. As a result, the bottom coverage (e.g., the ratio of material being deposited on the bottom of the contact compared to the amount deposited on the field of the contact) is substantially higher for IPVD than for PVD. Collectively, when referring to IPVD or PVD in a general sense, the term sputtered or sputtering will be used (e.g., sputtered TiN).

Generally, for TiN to be a good barrier material, it must be deposited over a region in which it does not “compete” with silicon. However, the annealing process makes the use of TiN problematic. That is, as a practical matter, TiN will not be deposited such that there is a one-to-one correspondence between the nitrogen atoms with the titanium atoms. Thus, there will be some “free” titanium atoms in the film.

Hence, when the anneal is performed to attempt to repair the deficiencies in the TiN to make the nitrogen available to convert “free” titanium to TiN, there will be a competing reaction of the “free” titanium (when formed over silicon) with the underlying silicon (e.g., which also reacts at a lower temperature than TiN). Thus, during the anneal, the titanium is more likely to react with the silicon than the nitrogen. Hence, a portion of the film will be converted to TiN and a portion will be reacted with silicon, thereby compromising the barrier which is to be repaired/formed. Hence, a barrier is desired which does not require two steps to make (e.g., deposition of TiN and then annealing to further make more/better TiN). However, with TiN, such a good barrier is not possible.

Thus, to replace the TiN and avoid the above problems, PVD and IPVD tungsten (W) have been used. Indeed, sputtered tungsten is known to be a superior barrier to fluorine attack when integrated with a CVD tungsten stud.

However, in contacts to silicide, this barrier prohibits oxides in the silicide from being reduced in the subsequent anneal process. It is noted that the oxides are typically present due to contact etches that oxidize, or other prior operations such as silicide anneals and also due to routine exposure to the ambient. The oxides within the contact result in an oxide layer below the sputtered tungsten barrier which causes high contact resistance and yield loss. Thus, the oxides are the result of prior processing up to and including the sputtered titanium, and the hydrogen is introduced during the anneal process to reduce them.

Thus, the superior barrier properties of sputtered tungsten are a disadvantage where oxides exist in the underlying structure because of the high contact resistance and yield loss. These oxides are present in silicided structures or introduced during the titanium deposition. Again, tungsten prohibits hydrogen-reduced oxides during the anneal from diffusing through it.

Therefore, a requirement for the barrier must initially be that hydrogen reduced oxides can diffuse through it. Titanium Nitride accomplishes this. However, it is not adequate to prevent a fluorine attack during the CVD tungsten process.

Hence, prior to the invention, there has been no method in which an excellent barrier material has been provided and yet which allows oxides to diffuse through the barrier.

Further, as device geometeries reduce <0.25 microns, it is increasingly difficult to deposit void-free CVD W without utilizing extremely aggressive CVD W chemistries. For example, it is known that using SIH₄ (silane) results in a less aggressive deposition of CVD W, but that it also results in voids. By not using silane, void-free CVD W depositions result, but also results in fluorine attacking the silicide when used with a TiN barrier. These are known as “worm holes”. Using a sputtered W barrier reduces the void problem in CVD W to simply the inherent characteristics of the CVD W process space.

### SUMMARY OF THE INVENTION

In view of the foregoing and other problems, disadvantages, and drawbacks of the conventional methods and structures, an object of the present invention is to provide a method (and structure produced thereby) for forming a liner in a contact.

In a first aspect, a method for forming a liner in a contact includes depositing a first layer of refractory metal, annealing the first layer of refractory metal, and sputter depositing a second layer of refractory metal or a compound or an alloy thereof, onto the annealed first layer of refractory metal.

In a preferred embodiment, another layer (e.g., a third layer) of refractory metal or a compound or an alloy thereof, is deposited onto the first refractory metal layer prior to the annealing.

With the unique and unobvious aspects of the present invention, a method is provided in which a barrier (liner), initially, allows hydrogen reduced oxides to diffuse through it during an annealing, and in which a good barrier is provided to prevent a fluorine attack during a subsequent processing (e.g., a CVD metal, such as tungsten, process). Hence, the oxides are not present to the silicide.

Further, using sputtered W as a barrier allows for a larger process window in the subsequent CVD W process where fluorine attack is a concern.

### BRIEF DESCRIPTION OF THE DRAWINGS

The foregoing and other objects, aspects and advantages will be better understood from the following detailed description of a preferred embodiment of the invention with reference to the drawings, in which:

FIGS. 1-6 illustrate processing steps of a method according to a preferred embodiment of the present invention in which:

FIG. 1 illustrates a method 100 according to the preferred embodiment as described in relation to the structure shown in FIGS. 2-6;

FIG. 2 illustrates a structure in which a layer of refractory metal (e.g., a first layer) is deposited;

FIG. 3 illustrates an optional step of depositing another layer (e.g., an optional second layer) of refractory metal (or compound or alloy thereof) onto the first refractory metal layer;

FIG. 4 illustrates an annealing of the structure and the resultant structure;

FIG. 5 illustrates sputter depositing of another refractory metal (or compound or alloy thereof);

FIG. 6 illustrates filling the contact with a metal to complete a contact; and

FIG. 7 is a graph showing yield (SRAM) for different experiments illustrating that the yield for the method of the present invention is higher than the conventional methods.

### DETAILED DESCRIPTION OF PREFERRED EMBODIMENTS OF THE INVENTION

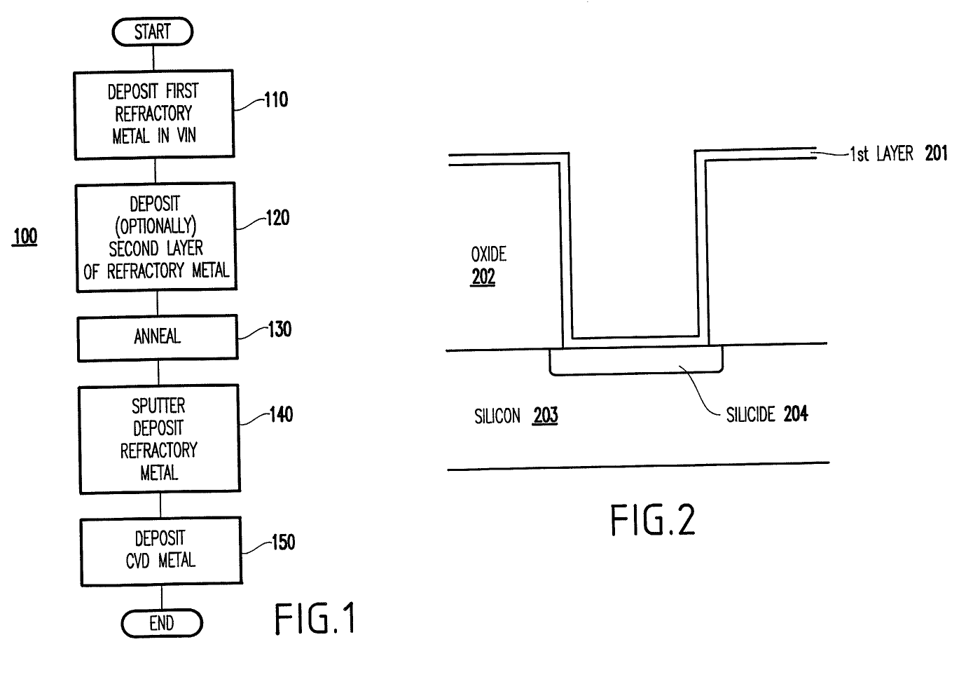

Referring now to the drawings, and more particularly to FIGS. 1-7, there is shown a preferred embodiment of the method and structure according to the present invention.

Generally, as described in further detail below, the method of the invention is to deposit a refractory metal or alloy such as titanium (or optionally a compound metal layer such as Ti/TiN), anneal the structure in a forming gas (e.g., N₂ with 5% H₂), and then deposit PVD, IPVD (or non fluorine CVD) refractory metal (e.g., such as tungsten). A key aspect of the invention is that, prior to the invention, a sputtered refractory metal (e.g., tungsten or ti-nitride) has not been successfully integrated at contacts to silicide whether deposited by conventional PVD or IPVD.

As mentioned above, sputtered tungsten (W) is known to be a superior barrier to fluorine attack when integrated with a CVD W stud. However, in contacts to silicide, this barrier prohibits oxides in the silicide from being reduced in the subsequent anneal process. This results in an oxide layer below the sputtered tungsten barrier which causes high contact resistance and yield loss.

Hence, the superior barrier properties of sputtered tungsten are a disadvantage where oxides exist in the underlying structure. These oxides are present in silicided structures or introduced during the titanium deposition. Tungsten prohibits hydrogen reduced oxides during the anneal from diffusing through it. Therefore, the method of the invention enables the barrier initially to allow hydrogen-reduced oxides (if any) to diffuse through it. While the conventional titanium Nitride allows such diffusion, it is not adequate to prevent fluorine attack during the CVD W process.

### Preferred Embodiment

The invention utilizes the superior barrier properties of PVD (or IPVD) refractory metal (e.g., tungsten) in silicided contacts, while allowing oxides in or on top of the silicide to be reduced during the anneal.

As mentioned above, in the conventional processes, a titanium/titanium nitride liner allows for reduced oxides to diffuse during the anneal, but is inadequate as a barrier to fluorine in subsequent CVD tungsten processing. This process window shrinks at geometries below 0.25 μm as design compromises, photo/etch limitations and CVD W fill coverage become increasingly difficult. This is particularly so with borderless contacts/shallow trench isolation (STI) junctions.

Turning to the flowchart of FIG. 1 and to FIGS. 2-6 which respectively show the structure of the invention formed at each step, the method 100 of forming a liner in a contact includes a first step 110 of depositing a layer of refractory metal 201 in the contact (e.g., see FIG. 2). The contact is formed by an opening in an oxide 202 formed on a silicon substrate 203. A silicide 204 is formed at the bottom of the contact. The refractory metal preferably is titanium. Tungsten is not preferable as the first metal since tungsten does not have good adhesion to the dielectric. Preferably, the deposition is performed by PVD or IPVD, and the first layer has a thickness of between about 50 Å to about 300 Å .

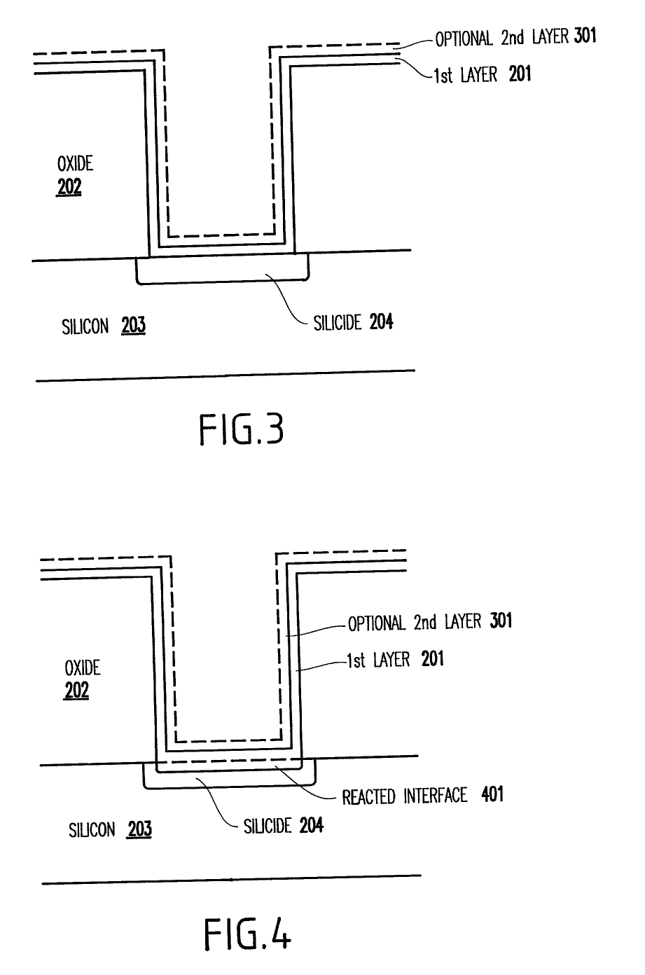

In step 120, as shown in FIG. 3, a second layer 301 of refractory metal (or a compound or an alloy thereof) is optionally deposited on the first layer of refractory metal 201. The second layer 301 of refractory metal preferably is titanium nitride. Preferably, the deposition is performed by PVD or IPVD, and the second layer 301 has a thickness of between about 50 Å to about 1000 Å.

In step 130, as shown in FIG. 4, the structure is annealed. Preferably, the annealing temperature is within a range of about 500° C. to about 700° C. depending upon the refractory metals being employed and depending upon whether a single wafer chamber or a batch chamber is being used. Preferably, the ambient is any one or combination of nitrogen, hydrogen or ammonia.

It is noted that, in contrast to the conventional methods, which use the anneal to make TiN as a barrier, an additional purpose of the annealing of the present invention is to activate the interface between the titanium and the contacted silicon/silicide. The reacted interface is shown at reference numeral 401 in FIG. 4. Thus, the invention allows titanium, Ti/TiN, tantalum, or another refractory metal to be deposited which can activate the region to reduce contact resistance, not to provide a barrier as in the conventional methods. In the conventional methods, as discussed above, which attempt to not only activate the region but also to provide a barrier, as the geometries shrink, it is difficult for both of these purposes to occur since, at the bottom of the contact, the contact is not fully landed on the silicide, but rather lands in part on the field isolation. That is, there are many features and irregularities at the bottom of the silicon which prevent such landing. Thus, the invention provides the annealing to activate the interface, and sputtered tungsten becomes the barrier.

In step 140, as shown in FIG. 5, after the annealing of the structure, another layer of refractory metal 501 (or a compound or an alloy thereof) is deposited (e.g., sputter deposited) on the optional second layer 301. The third layer 501 of refractory metal preferably is tungsten and forms the above-mentioned barrier. Preferably, the deposition is performed by PVD deposition or IPVD. The third refractory metal 501 layer preferably has a thickness of between about 50 Å to about 500 Å.

It is noted that the “barrier” provided by the invention is a barrier to chemical attack and metallurgical attack. Tungsten is a good barrier, as compared to TiN which is a poor barrier for the reasons stated above. TiN requires repair after it has been deposited and requires the anneal to enhance it. Even CVD TiN requires plasma treatments thereon in the reactor, to make TiN a barely sufficient barrier. Thus, tungsten is a vastly superior barrier material.

Thus, the liner is formed, as shown in FIG. 5.

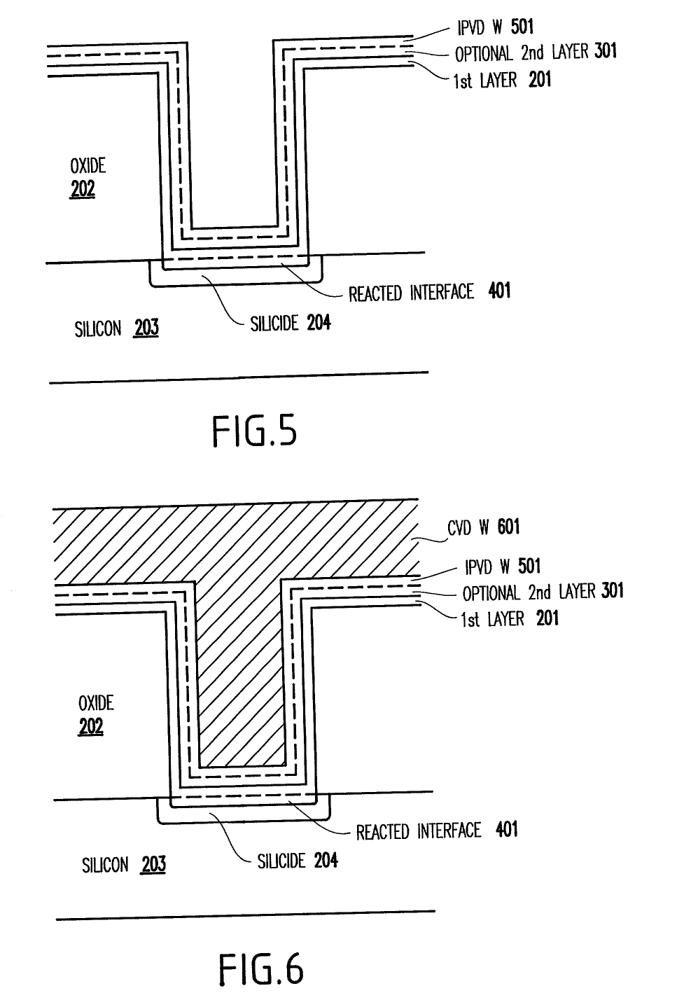

Thereafter, in step 150 as shown in FIG. 6, the contact (plug) is filled with, for example, a CVD metal 601 such as CVD tungsten, aluminum, copper, etc., to form the contact.

It is noted that the metal used for the filling of the plug/contact need not be the same as the metal used as the barrier. Thus, for example, sputtered tungsten could be used as the barrier and aluminum (or tungsten) could be used for filling the plug. Hence, there is not necessarily a relationship between the sputtered metal and the metal being deposited thereafter to fill the plug. Indeed, tungsten is a very good metallurgical barrier and is preferable, as aluminum and silicon will react together under temperature, so that silicon migration occurs which causes silicon spiking because the silicon diffuses into the aluminum, thereby causing spiking of the contacts. Hence, a good metallurgical barrier such as tungsten is preferred, to avoid such spiking.

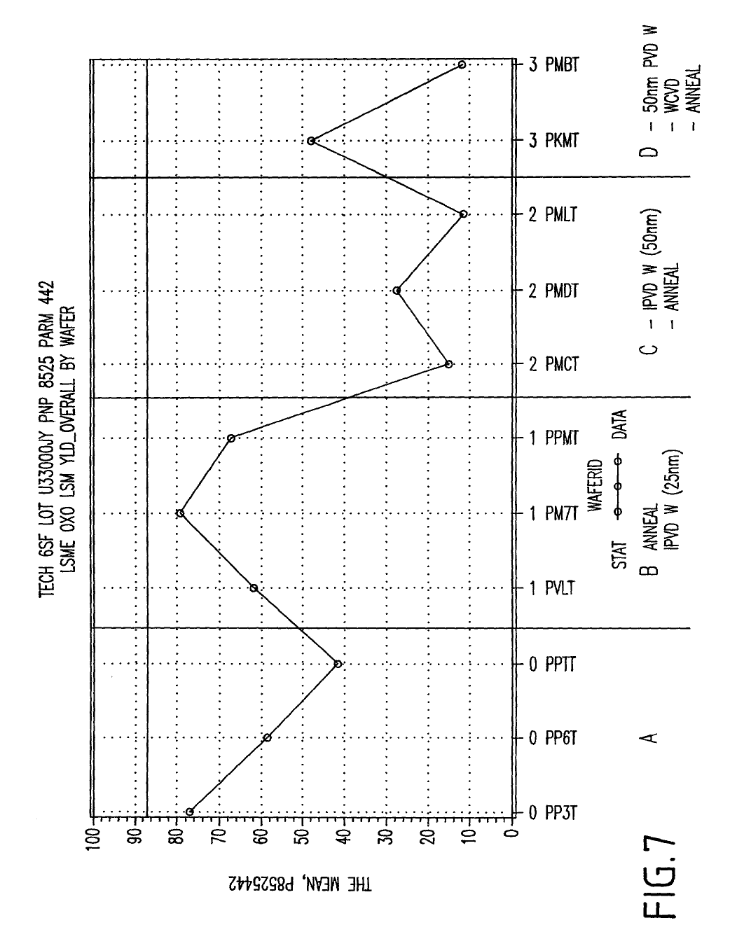

FIG. 7 is a graph showing yield on a 6.6 sq micron SRAM cell for different experiments illustrating that the yield for the method of the present invention is higher than the conventional methods. Further, FIG. 7 shows that an anneal post IPVD is bad for yield.

More specifically, FIG. 7 shows four (4) groups of wafers respectively processed with a conventional liner/barrier, the present invention, and two (2) variations to illustrate the criticality of process integration.

| Group | Process flow |
|---|---|
| A | IPVD Ti ==> IPVD TiN ==> ANNEAL ==> WCVD |
| B | IPVD Ti ==> IPVD TiN ==> ANNEAL ==> IPVD |
| | Tungsten ==> WCVD |
| C | IPVD Ti ==> IPVD TiN ==> IPVD Tungsten ==> |
| | ANNEAL ==> WCVD |
| D | IPVD Ti ==> IPVD TiN ==> PVD Tungsten ==> WCVD ==> |
| | ANNEAL |

The intent of the experiment was to determine if sputtered W could be used as a barrier in contacts to silicon and where the anneal needed to be placed so that the contacts would yield higher than group A, which is the conventional process flow. Shown below is the mean yield and standard deviation of the four (4) groups. Clearly, Group B (the preferred method) yielded higher with a tighter distribution than all other cells, including the conventional process flow (Group A), thereby showing that barrier selection and process integration are critical for improved yields. Group C and D show the yield to be significantly lower and is due to highly resistive contacts. The standard deviation in Group A shows that, while a TiN barrier can produce yielding die, the variations introduced from wafer to wafer show that TiN is insufficient to prevent fluorine attack.

| Group | Yield Mean | Yield Standard Deviation |
|---|---|---|
| A | 59 | 17.5 |
| B | 69.7 | 8.3 |
| C | 18 | 7.9 |
| D | 35 | 32 |

Thus, as described above, with the unique and unobvious aspects of the invention, the superior barrier properties of PVD tungsten can be utilized in silicided contacts, while allowing oxides to be diffused during the anneal process.

While the invention has been described in terms of preferred embodiments, those skilled in the art will recognize that the invention can be practiced with modification within the spirit and scope of the appended claims.

What is claimed is:

1. A method for forming a liner in a contact, comprising:
depositing a first layer of refractory metal into a contact formed in a substrate;
annealing the first layer; and
sputter depositing a second layer of refractory metal or a compound or an alloy thereof, over said first layer of refractory metal.

2. The method of claim 1, further comprising:
depositing a third layer of refractory metal or a compound or an alloy thereof, onto the first refractory metal layer prior to the annealing.

3. The method of claim 1, wherein said first layer of refractory metal comprises titanium.

4. The method of claim 2, wherein said third layer of refractory metal comprises titanium nitride.

5. The method of claim 1, wherein said second layer of refractory metal comprises tungsten.

6. The method of claim 1, wherein said substrate comprises one of a silicide, a doped Si, and a dielectric region.

7. The method of claim 1, wherein said annealing is for activating an interface between said first refractory metal and an underlying substrate.

8. The method of claim 5, wherein said tungsten comprises one of plasma vapor deposited (PVD) tungsten and ionized plasma vapor deposited (IPVD) tungsten.

9. The method of claim 1 wherein said deposition of said first refractory metal layer is performed by one of plasma vapor deposition (PVD) and ionized plasma vapor deposition (IPVD).

10. The method of claim 1, wherein said first refractory metal layer has a thickness of between about 50 Å to about 300 Å.

11. The method of claim 2, wherein said third layer of refractory metal is deposited by one of plasma vapor deposition (PVD) and ionized plasma vapor deposition (IPVD).

12. The method of claim 2, wherein said third refractory metal layer has a thickness of between about 50 Å to about 1000 Å.

13. The method of claim 1, wherein said annealing is performed within a range of about 500° C. to about 700° C. in an ambient of one or a combination of nitrogen, hydrogen and ammonia.

14. The method of claim 1, wherein said first refractory metal layer comprises any of titanium, tantalum, and a bilayer of titanium and TiN.

15. The method of claim 1, wherein said second layer is deposited by one of PVD and IPVD.

16. The method of claim 1, wherein the second refractory metal layer has a thickness of between about 50 Å to about 500 Å.

17. A method of forming a contact in a semiconductor material, comprising:
forming a contact in a substrate;
depositing a first layer of refractory metal into said contact;
annealing the first layer;
sputter depositing a second layer of refractory metal or a compound or an alloy thereof, over said first layer of refractory metal; and
filling said contact with a metal, to form said contact.

18. The method of claim 17, wherein said metal filling the contact comprises a chemical vapor deposited (CVD) tungsten.

19. The method of claim 18, wherein said metal filling the contact comprises aluminum.

20. A method of forming an electrical contact to a silicide, comprising:
depositing one of a titanium layer and a titanium/titanium nitride bi-layer as a barrier liner;
performing an anneal after said barrier liner is deposited to allow any hydrogen-reduced oxides in the silicide to diffuse through the barrier liner; and
sputter depositing tungsten onto said barrier liner.

21. A liner for a contact in a semiconductor material, comprising:
a first layer of refractory metal deposited into a contact formed in a semiconductor substrate; and
a second layer of refractory metal or a compound or an alloy thereof, sputter deposited over the first layer of refractory metal after said first layer has been annealed.

22. The liner of claim 2 1, further comprising:
a third layer of refractory metal or a compound or an alloy thereof formed over said first layer of refractory metal prior to annealing.

23. The liner of claim 21, wherein said first layer of refractory metal comprises titanium.

24. The liner of claim 22, wherein said third layer of refractory metal comprises titanium nitride.

25. The liner of claim 21, wherein said second layer of refractory metal comprises tungsten.

26. A contact formed in a semiconductor material, comprising:
a contact portion formed in a substrate;
a liner formed in said contact portion, said liner including a first layer of refractory metal formed in said contact portion, and a second layer of refractory metal or a compound or an alloy thereof, sputter deposited over said first layer of refractory metal after said first layer is annealed; and
a metal filling said contact portion, to form said contact.

27. The contact of claim 26, further comprising:
a third layer of refractory metal or a compound or an alloy thereof, formed on the first refractory metal layer prior to annealing.

28. The contact of claim 26, wherein said first layer of refractory metal comprises titanium.

29. The contact of claim 27, wherein said third layer of refractory metal comprises titanium nitride.

30. The contact of claim 26, wherein said second layer of refractory metal comprises tungsten.

31. The contact of claim 26, wherein said substrate comprises one of a silicide, a doped Si, and a dielectric region.

32. The contact of claim 30, wherein said tungsten comprises one of plasma vapor deposited (PVD) tungsten and ionized plasma vapor deposited (IPVD) tungsten.

34. The contact of claim 26,-wherein said first refractory metal layer has a thickness of between about 50 Å to about 300 Å.

35. The contact of claim 27, wherein said third refractory metal layer has a thickness of between about 50 Å to about 1000 Å.

36. The contact of claim 26, wherein said first refractory metal layer comprises any of titanium, tantalum, and a bilayer of titanium and TiN.

37. The contact of claim 26, wherein the second refractory metal layer has a thickness of between about 50 Å to about 500 Å.

38. A semiconductor device, comprising:
a semiconductor having a contact to a substrate formed therein;
a liner formed in said contact, said liner including a first layer of refractory metal formed in said contact and for being annealed, and a second layer of refractory metal or a compound or an alloy thereof, sputter deposited over said first layer of refractory metal after said first layer is annealed; and
a metal filling said contact.

39. The device of claim 38, further comprising:
a third layer of refractory metal or a compound or an alloy thereof, formed on the first refractory metal layer prior to annealing.

40. The device of claim 38, wherein said first layer of refractory metal comprises titanium.

41. The device of claim 39, wherein said third layer of refractory metal comprises titanium nitride.

42. The device of claim 38, wherein said second layer of refractory metal comprises tungsten.

43. The device of claim 38, wherein said substrate comprises one of a silicide, a doped Si, and a dielectric region.

44. The device of claim 42, wherein said tungsten comprises one of plasma vapor deposited (PVD) tungsten and ionized plasma vapor deposited (IPVD) tungsten.

45. The device of claim 38, wherein said first refractory metal layer has a thickness of between about 50 Å to about 300 Å.

46. The device of claim 39, wherein said third refractory metal layer has a thickness of between about 50 Å to about 1000 Å.

47. The device of claim 38, wherein said first refractory metal layer comprises any of titanium, tantalum, and a bilayer of titanium and TiN.

48. The device of claim 38, wherein the second refractory metal layer has a thickness of between about 50 Å to about 500 Å.

49. A method of forming a semiconductor device, comprising:
forming a contact to a semiconductor substrate;
depositing a first layer of refractory metal into said contact;
annealing the first layer;
sputter depositing a second layer of refractory metal or a compound or an alloy thereof, over said first layer of refractory metal; and
filling said contact with a metal.
